(19) United States
(12) Patent Application Publication
(10) Pub. No.: US 2025/0113580 A1
(43) Pub. Date: Apr. 3, 2025

(54) BACKSIDE SOURCE/DRAIN TRANSISTOR CONTACT FLOW WITH SELECTIVE ETCH MATERIALS FOR ROBUST CONNECTIVITY

(71) Applicant: Intel Corporation, Santa Clara, CA (US)

(72) Inventors: Leonard Guler, Hillsboro, OR (US); Shaun Mills, Hillsboro, OR (US); Joseph D'Silva, Hillsboro, OR (US); Ehren Mannebach, Beaverton, OR (US); Mauro Kobrinsky, Portland, OR (US); Charles H. Wallace, Portland, OR (US); Kalpesh Mahajan, Portland, OR (US); Vivek Vishwakarma, Vancouver, WA (US); Dincer Unluer, Hillsboro, OR (US); Jessica Panella, Banks, OR (US)

(73) Assignee: Intel Corporation, Santa Clara, CA (US)

(21) Appl. No.: 18/374,528

(22) Filed: Sep. 28, 2023

(51) Int. Cl. H01L 29/417; H01L 29/06; H01L 29/423; H01L 29/775; H01L 29/786

(52) U.S. Cl. CPC H10D 64/256; H10D 30/43; H10D 30/6735; H10D 30/6757; H10D 62/121

(57) ABSTRACT

Devices, transistor structures, systems, and techniques are described herein related to contacting source and drain transistor structures from the device backside at small dimensions and cell sizes. A first subset of dummy contact structures are removed and backfilled with contact metal and a first etch stop material. A second subset of dummy contact structures are removed and backfilled with contact metal and a second etch stop material. Subsequent metallization contacts to the first and second contacts are made using two masking/selective etch processes such that any misalignment to the other contact type does not allow contact due to the pertinent etch stop material.

### BACKGROUND

Higher performance, lower cost, increased miniaturization, and greater density of integrated circuits (ICs) are ongoing goals of the electronics industry. Backside interconnects are an important aspect for advancement in the semiconductor industry towards these goals. Backside interconnects, for example, can provide power from the backside of the transistor device. This offers advantages including a lower resistance path to power the transistor devices, opening space on the frontside of the transistor device layout, and others. This, in turn, improves transistor device performance metrics both in per power terms and per area terms.

However, difficulties persist in the deployment of backside power delivery and other backside transistor contacts. For example, ever shrinking cell sizes, contact overlap requirements, and backside distortion issues create a need for improved backside contact flows that improve the robustness of backside connectivity. The techniques and structures discussed herein offer improved backside contacts to transistor source/drain with reduced shorts, contact failures, and defect rates. Such improvements may become critical as the desire to deploy advanced transistor structures becomes even more widespread.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIG. 1 is a flow diagram illustrating methods for contacting transistor source and drain structures using a backside contact coloring flow;

FIGS. 2, 3, 4, 5, 6, 7, 8, 9, 10, 11, 12, 13, 14, 15, 16, 17, 18, 19, and 20 are isometric views or isometric projections of transistor structures evolving as the methods of FIG. 1 are practiced;

FIG. 21 is a cross-sectional side view of the transistor structure of FIG. 20 after continued backside metallization processing;

FIG. 22 illustrates exemplary systems employing transistor structures having field effect transistors with backside contact coloring; and

FIG. 23 is a functional block diagram of an electronic computing device, all in accordance with some embodiments.

### DETAILED DESCRIPTION

One or more embodiments or implementations are now described with reference to the enclosed figures. While specific configurations and arrangements are discussed, it should be understood that this is done for illustrative purposes only. Persons skilled in the relevant art will recognize that other configurations and arrangements may be employed without departing from the spirit and scope of the description. It will be apparent to those skilled in the relevant art that techniques and/or arrangements described herein may also be employed in a variety of other systems and applications other than what is described herein.

Reference is made in the following detailed description to the accompanying drawings, which form a part hereof, wherein like numerals may designate like parts throughout to indicate corresponding or analogous elements. It will be appreciated that for simplicity and/or clarity of illustration, elements illustrated in the figures have not necessarily been drawn to scale. For example, the dimensions of some of the elements may be exaggerated relative to other elements for clarity. Further, it is to be understood that other embodiments may be utilized, and structural and/or logical changes may be made without departing from the scope of claimed subject matter. It should also be noted that directions and references, for example, up, down, top, bottom, over, under, and so on, may be used to facilitate the discussion of the drawings and embodiments and are not intended to restrict the application of claimed subject matter. Therefore, the following detailed description is not to be taken in a limiting sense and the scope of claimed subject matter defined by the appended claims and their equivalents.

In the following description, numerous details are set forth. However, it will be apparent to one skilled in the art, that the present invention may be practiced without these specific details. In some instances, well-known methods and devices are shown in block diagram form, rather than in detail, to avoid obscuring the present invention. Reference throughout this specification to “an embodiment” or “one embodiment” means that a particular feature, structure, function, or characteristic described in connection with the embodiment is included in at least one embodiment of the invention. Thus, the appearances of the phrase “in an embodiment” or “in one embodiment” in various places throughout this specification are not necessarily referring to the same embodiment of the invention. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description of the invention and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items. Herein, the term “predominantly” indicates not less than 50% of a particular material or component while the term “substantially pure” indicates not less than 99% of the particular material or component and the term “pure” indicates not less than 99.9% of the particular material or component. Unless otherwise indicated, such material percentages are based on atomic percentage. Herein the term concentration is used interchangeably with material percentage and also indicates atomic percentage unless otherwise indicated.

The terms “coupled” and “connected,” along with their derivatives, may be used herein to describe structural relationships between components. It should be understood that these terms are not intended as synonyms for each other. Rather, in particular embodiments, “connected” may be used to indicate that two or more elements are in direct physical or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause an effect relationship, an electrical relationship, a functional relationship, etc.).

The terms “over,” “under,” “between,” “on”, and/or the like, as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening features. The term immediately adjacent indicates such features are in direct contact. Furthermore, the terms “substantially,” “close,” “approximately,” “near,” and “about,” generally refer to being within +/−10% of a target value. The term layer as used herein may include a single material or multiple materials. As used in throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C. The terms “lateral”, “laterally adjacent” and similar terms indicate two or more components are aligned along a plane orthogonal to a vertical direction of an overall structure. As used herein, the terms “monolithic”, “monolithically integrated”, and similar terms indicate the components of the monolithic overall structure form an indivisible whole not reasonably capable of being separated.

Devices, transistor structures, integrated circuit dies, apparatuses, systems, and techniques are described herein related to backside contacts using a backside contact coloring flow.

As discussed, backside interconnects or backside metallization layers are an important aspect for advancement in the semiconductor industry. Such backside interconnects are vertically opposite from frontside metallization layers with respect to a device layer therebetween. For example, the frontside metallization layers are over a device layer including transistors and the backside metallization layers are under the transistors (or over the transistors from the alternative perspective). During frontside processing, dummy contact structures may be fabricated such that they are in contact with source and drain structures and extend toward the backside of the device layer. After frontside metallization and other processing, the wafer is attached to a carrier and the substrate backside is removed to expose the dummy contact structures.

The backside contact coloring flow discussed herein resolves or mitigates problems related to landing on the contact structures that replace the dummy contact structures. Notably, as feature and cell sizes decrease, it becomes difficult to accurately land metallization features (e.g., metal lines) on the backside contact structures due to backside distortion issues and other difficulties. Such backside contact problems may be evidenced as landing on incorrect backside contacts due to alignment and etch placement errors. For example, ever shrinking cells sizes, contact overlap requirements, and backside distortion issues create a need for new techniques to provide robust back-side connectivity to transistor contact structures. As discussed further herein, the backside contact coloring flow replaces a first subset of dummy contact structures with a contact metal and a first etch stop material on the contact metal, and subsequently replaces a second subset of dummy contact structures with a contact metal and a second etch stop material on the contact metal such that the first and second etch stop materials have an etch selectivity therebetween. The metallization features are then formed in two passes each including lithography, anisotropic etch, and metallization, with each etch being selective to the pertinent etch stop material. Any attempted etch overlap onto the incorrect contact structure (e.g., due to lithographic misalignment) is then blocked by the etch stop material on the incorrect contact structure due to the discussed etch selectivity. Thereby, the process bandwidth for landing on the pertinent contact structure from the backside is increased for a more robust backside contact and metallization process. It is noted the lithographic process used to open and remove the first and second subsets of dummy contact structures has an inherently larger process window due to the etch removal of the first and second dummy contact structures being isotropic. Therefore, the openings to the first and second dummy contact structures do not need to align perfectly to the first and second dummy contact structures but instead the etch selectivity from neighboring materials and structures provides a relatively wide lithographic process window. Other advantages of the backside contact coloring flow discussed herein will be evident based on the following discussion.

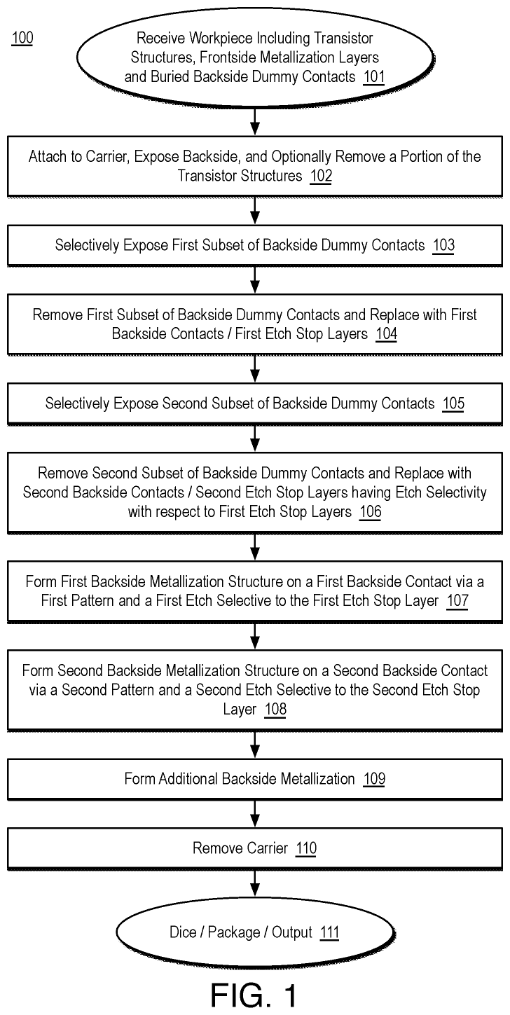

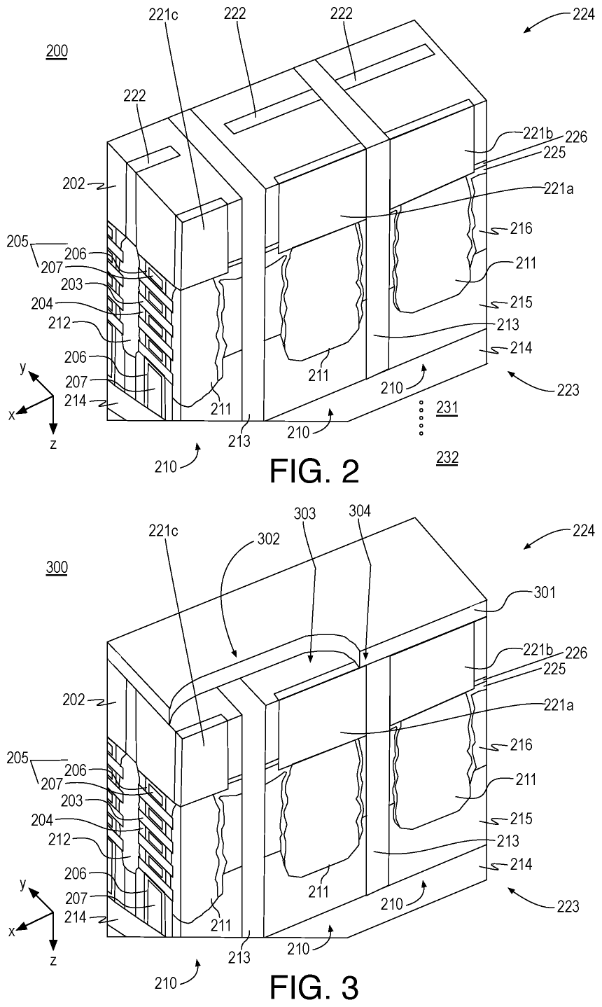

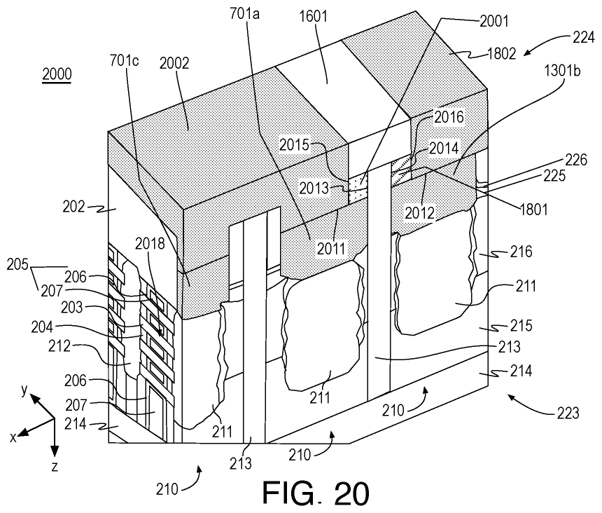

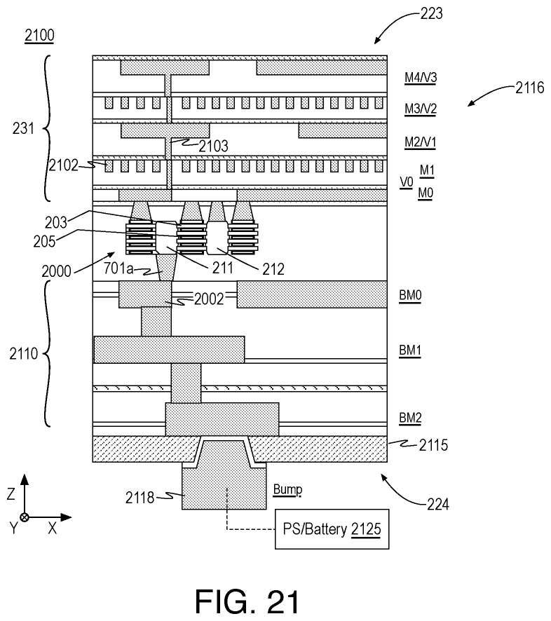

FIG. 1 is a flow diagram illustrating methods 100 for contacting transistor source and drain structures using a backside contact coloring flow, arranged in accordance with at least some implementations of the present disclosure. FIGS. 2, 3, 4, 5, 6, 7, 8, 9, 10, 11, 12, 13, 14, 15, 16, 17, 18, 19, and 20 isometric views or isometric projections of transistor structures evolving as methods 100 are practiced, arranged in accordance with some embodiments of the disclosure. FIG. 21 is a cross-sectional side view of the transistor structure of FIG. 20 after continued backside metallization processing, arranged in accordance with some embodiments of the disclosure.

Methods 100 begin at input operation 101, where a workpiece is received. The workpiece includes transistor structures in a device layer and frontside metallization layers over the transistor structures. The workpiece further includes buried backside dummy contacts that extend from source and/or drain structures of the transistor structures toward the backside of the workpiece. As used herein the term frontside of a transistor structure or a workpiece indicates the side (or the direction of the side) being built up during front end of line (FEOL) processing of a transistor structure, typically over a wafer substrate, in accordance with the accepted use of the term frontside in the art. The backside is then opposite the frontside and is the side opposite the buildup direction (e.g., a negative z-direction).

For example, a substrate may be received for processing such that a transistor or transistor structure has been fabricated over the substrate. In some embodiments, the transistor or transistor structure includes semiconductor structure(s) extending between a source structure and a drain structure. Gate structures (e.g., a gate dielectric and a gate electrode) are between the source and drain structures such that the gate structure is adjacent to a channel region of the one or more semiconductor structures. The discussed backside dummy contacts are in contact with the source structure and the drain structure and extend toward the backside and may, for example, extend into the substate. For example, the transistor may be part of a transistor layer or device layer formed over the substrate. Any number of metallization layers may be formed over the frontside of the transistors of the device layer to interconnect the transistors, provide signal routing, and so on.

Processing continues at operation 102, where the frontside of the workpiece received at operation 110 is attached to a carrier and the backside is exposed. In some embodiments, the partially fabricated workpiece is mounted, by its frontside, to a carrier such as a carrier wafer, and the discussed dummy contact structures are exposed by removal of the substrate of the workpiece. The workpiece may be mounted to the carrier using any suitable technique or techniques such as application of an adhesive film between the workpiece and carrier. The dummy contact structures are the exposed using any suitable technique or techniques such as backside substrate removal processing including backside grind, backside etch, or the like. In some embodiments, portions of the transistor structure are then modified or removed. For example, subfin semiconductor material may be removed and backfilled with a dielectric material such as an oxide, Notably, a subfin semiconductor material may cause difficulties such as leakage if not removed.

FIG. 2 is an isometric view of a transistor structure 200 including exposed backside dummy contact structures 221, 222 in contact with source structures 211 and drain structures 212. For example, backside dummy contact structures 221, 222 are in contact with backside surfaces of source/drain structures 211, 212 and are exposed at a backside 224 of transistor structure 200. As shown, transistor structure 200 includes a number of transistors 210 or transistor structures. Each of transistors 210 include a number of semiconductor structures 203 that are or include a semiconductor material. Transistors 210 and semiconductor structures 203 may be implemented in an integrated circuit, for example. Semiconductor structures 203 may also be characterized as ribbons, semiconductor ribbons, or the like. Although illustrated with respect to ribbons of, for example, gate all around (GAA) field effect transistors (GAA-FETs) 210, any suitable transistor architecture may be used.

As shown, semiconductor structures 203 extend between source structures 211 and drain structures 212. Furthermore, a gate structure 205 is between source structure 211 and drain structure 212 and is adjacent a channel region of semiconductor structures 203. As used herein, the term channel region indicates a region or portion of a material or structure that is manipulated by a gate to operate the transistor. Notably, the transistor need not be in operation for a region to be a channel region.

Transistor structure 200 may include and be formed over a substrate, which is subsequently removed. In some embodiments, semiconductor structures 203 may be formed of the same material as the substrate. However, semiconductor structures 203 may also be formed over but discontinuous with the substrate material. Semiconductor structures 203 may be or may include any suitable semiconductor material or materials such as silicon, germanium, silicon germanium, a III-V material, nanomaterials, transition metal dichalcogenide materials, or others. In some embodiments, semiconductor structures 203 are formed from fins over the substrate. In some embodiments, a portion of semiconductor structures 203 (e.g., a subfin) is buried in a dielectric material or dielectric layer 202, and subsequently removed and replaced by the same dielectric material to form dielectric layer 202. In some embodiments, dielectric layer 202 is a silicon oxide (e.g., a layer including silicon and oxygen). However, other dielectric materials may be used. As used herein the term dielectric material indicates a material in which electric current does not flow freely.

The channel region of each of semiconductor structures 203 is surrounded by a gate structure 205. Gate structure 205 includes, for example, a gate insulator 206 on at least a portion of each of semiconductor structures 203 and a gate electrode 207 on gate insulator 206. Gate insulator 206 may be silicon oxide, aluminum oxide, or a high-k dielectric, such as hafnium oxide. For example, gate insulator 206 may include elements such as hafnium, silicon, oxygen, titanium, tantalum, lanthanum, aluminum, zirconium, barium, strontium, yttrium, lead, scandium, niobium, or zinc. Gate electrodes 207 may include any suitable work function metal for transistor gate control such as tantalum, titanium, aluminum, ruthenium, or alloys of such materials and a fill metal such as tungsten. As shown, semiconductor structures 203 extend between a source structure 211 (or source) and a drain structure 212 (or drain). Gate insulator 206 and gate electrode 207 of gate structure 205 are adjacent channel regions of semiconductor structures 203 to form a three-terminal transistor device. Spacers 204 separate gate structures 205 from source structure 211 and drain structure 212, and spacers 204 may be any suitable dielectric material(s).

As shown, a portion of gate electrode 207 (and gate insulator 206) may extend over transistor 210 toward a frontside 223 of transistor structure 200 to provide a frontside gate or gate contact, and may contact a frontside metallization feature (not shown). In addition, source structure 211 and/or drain structure 212 may be coupled to frontside source/drain contacts 215, which may also contact frontside metallization features (not shown). As shown, portions of source structures 211 and drain structures 212 may be embedded in dielectric material 216. In some embodiments, dielectric material 216 is a silicon oxide (e.g., a layer including silicon and oxygen). However, other dielectric materials may be used. Frontside gate, source, and drain and/or frontside metallization features (not shown) may be embedded in a dielectric layer 214, which may be silicon oxide (e.g., a layer including silicon and oxygen) or any other suitable dielectric material. In addition, frontside metallization layers 231 may include the frontside metallization features, dielectric layer 214 and any number of additional frontside metallization levels (i.e., layers of metallization lines interconnected by metal vias, and embedded in dielectric materials). Such frontside metallization layers 231 is illustrated and discussed further herein with respect to FIG. 21.

Fabrication of transistor structure 200 may include formation of layers 225, 226 which may be any suitable materials. Transistors 210 may be separated from one another by isolation dielectric structures 213. Isolation dielectric structures 213 may be any suitable dielectric material such as silicon oxide (e.g., a layer including silicon and oxygen) or any other suitable dielectric material. Notably, isolation dielectric structures 213 may have an etch selectivity with respect to subsequent etch stop layers, as is discussed further herein below.

As shown, backside dummy contact structures 221, 222 are in contact with source structures 211 and drain structures 212, and backside dummy contact structures 221, 222 extend toward a backside 224 of semiconductor structure. Furthermore, backside dummy contact structures 221, 222 are exposed from backside 224. For example, transistor structure may be attached to or include a carrier wafer 232 (not shown), a substrate may be removed, and backside dummy contact structures 221, 222 may be revealed. Backside dummy contact structures 221a, 221b, 221c are to be selectively removed and replaced with contact structures. Backside dummy contact structures 221a, 221b, 221c may include any suitable material that has an isotropic etch selectivity with respect to other surrounding materials (e.g., dielectric layer 202 and isolation dielectric structures 213). This etch selectivity advantageously allows backside dummy contact structures 221a, 221b, 221c to be exposed using a relatively large lithographic opening that can overlap with surrounding structures and materials. In some embodiments, backside dummy contact structures 221a, 221b, 221c are titanium nitride (e.g., a material including titanium and nitrogen). However, other materials may be used.

In the following, backside contacts are formed and contacted by metallization structures using a contact coloring flow. Notably, the contacts of interest are formed at the locations of backside dummy contact structures 221a, 221b (with backside dummy contact structure 221c being in the same subset as backside dummy contact structure 221a). In this context, the contacts are both source contacts of different transistors 210, which are separated by isolation dielectric structure 213. However, the contacts may be any combination of source and drain contacts such as a source contact and a drain contact (of the same or different transistors 210) or two drain contacts (of different transistors 210), without limitation. Furthermore, such contact coloring may be extended to any number of contacts and dummy contact structures.

Returning to FIG. 1, processing continues at operation 103, where a first subset of the backside dummy contacts are selectively exposed while a second subset of the backside dummy contacts are selectively covered or obscured by a patterned material layer. The first subset and second subset of backside dummy contacts may be selectively exposed and covered using any suitable technique or techniques such as lithography techniques. For example, a resist layer, a hardmask layer, a multiple layer hardmask, or the like may be deposited and patterned using any suitable technique or techniques.

FIG. 3 is an isometric view of a transistor structure 300 similar to transistor structure 200 after formation of patterned layer 301. As discussed, patterned layer 301 may be a resist layer, a hardmask layer, a multiple layer hardmask, or other suitable patterning material. Patterned layer 301 may be formed using any suitable technique or techniques such as deposition and lithography operations. As shown, patterned layer 301 includes one or more openings 302 that expose a first subset of backside dummy contact structures including backside dummy contact structures 221a, 221c while covering a second subset of backside dummy contact structures including backside dummy contact structure 221b.

As discussed, due to the etch selectivity of backside dummy contact structures 221a, 221c relative to other exposed materials (e.g., an etch selectivity between titanium nitride and silicon oxide or other dielectric materials), opening 302 does not need to perfectly align with backside dummy contact structures 221a, 221c for effective removal of backside dummy contact structures 221a, 221c. For example, as shown with respect to exposure 303, portions of dielectric layer 202 and/or isolation dielectric structures 213 may be exposed by opening 302. Furthermore, as shown with respect to overlap 304, not all of top surfaces of backside dummy contact structures 221a, 221c need to be fully exposed to fully remove backside dummy contact structures 221a, 221c during subsequent etch processing.

Returning to FIG. 1, processing continues at operation 104, where the exposed first subset of the backside dummy contacts are selectively removed and replaced with a material stack including a backside contact (e.g., metal contact) on the source or drain exposed by removal of the backside dummy contact and a first etch stop material on the backside contact. As used herein, the term etch stop material indicates any material having an etch selectivity with respect to other materials such that, during etch processing, the etch stop material is not significantly removed such that an underlying material is still obscured by the etch stop material after etch processing.

The exposed first subset of backside dummy contacts may be removed using any suitable technique or techniques such as selective isotropic etch processing including wet etch processes. The contact metal and first etch stop material may be formed using any suitable technique or techniques. In some embodiments, a protective layer may be formed on lateral surfaces but not within the openings defined by the removed first subset of the backside dummy contacts (which have a high aspect ratio). The contact metal may then be deposited in the openings and planarized, followed by recess of the contact metal, deposition of the first etch stop material and planarization processing of the first etch stop material. Other processes may be deployed.

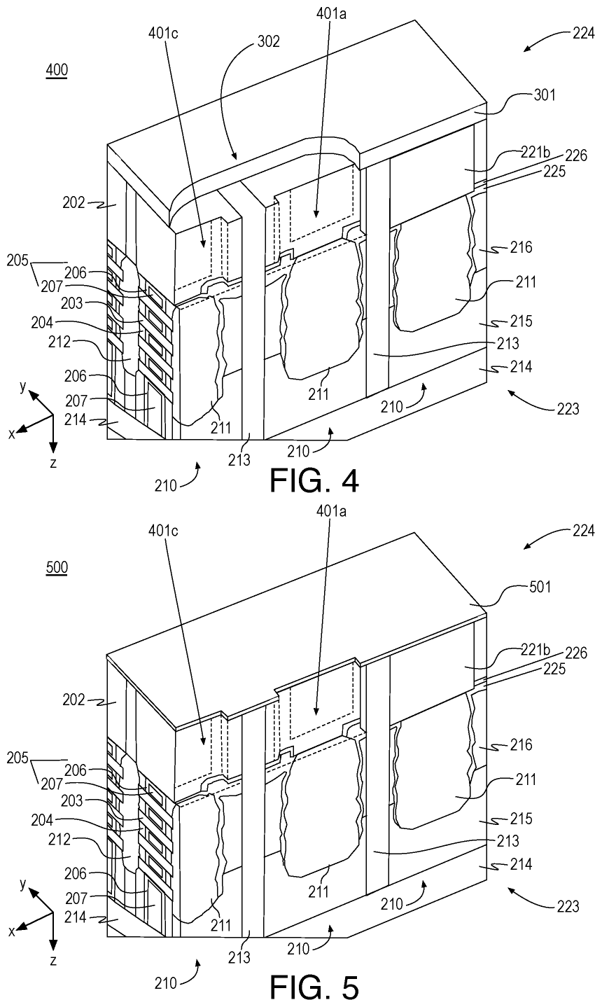

FIG. 4 is an isometric view of a transistor structure 400 similar to transistor structure 300 after a selective isotropic etch removes backside dummy contact structures 221a, 221c to form openings 401a, 401c. The selective isotropic etch may be any suitable etch process that is selective to the material of backside dummy contact structures 221a, 221c. In some embodiments, the selective isotropic etch is an isotropic wet etch process. Due to the selective nature of the etch process, backside dummy contact structures 221a, 221c are removed while other structures remain. As discussed, thereby, opening 302 does not need to perfectly align with backside dummy contact structures 221a, 221c. Notably, the selective isotropic etch exposes backside surfaces of source structures 211 and/or drain structures 212 associated with the first subset of backside dummy contact structures such as backside dummy contact structures 221a, 221c. The processing discussed with respect to FIGS. 3 and 4 may be characterized as a pinhole lithography and etch process.

FIG. 5 is an isometric view of a transistor structure 500 similar to transistor structure 400 after removal of patterned layer 301, and formation of a protective layer 501. Patterned layer 301 may be removed using any suitable technique or techniques such as dry and/or wet etch techniques. As discussed below, protective layer 501 aids in the formation of a contact metal and first etch stop material in openings 401a, 401c. Protective layer 501 may be formed using any suitable technique or techniques including sputter deposition such that protective layer 501 is deposited only on a top or backside surface while not depositing in openings 401a, 401c due to the high aspect ratio of openings 401a, 401c. Protective layer 501 may be any suitable protective material such as titanium nitride (e.g., a layer including titanium and nitrogen), silicon, titanium oxide (e.g., a layer including titanium and oxygen), aluminum nitride (e.g., a layer including aluminum and nitrogen), or others.

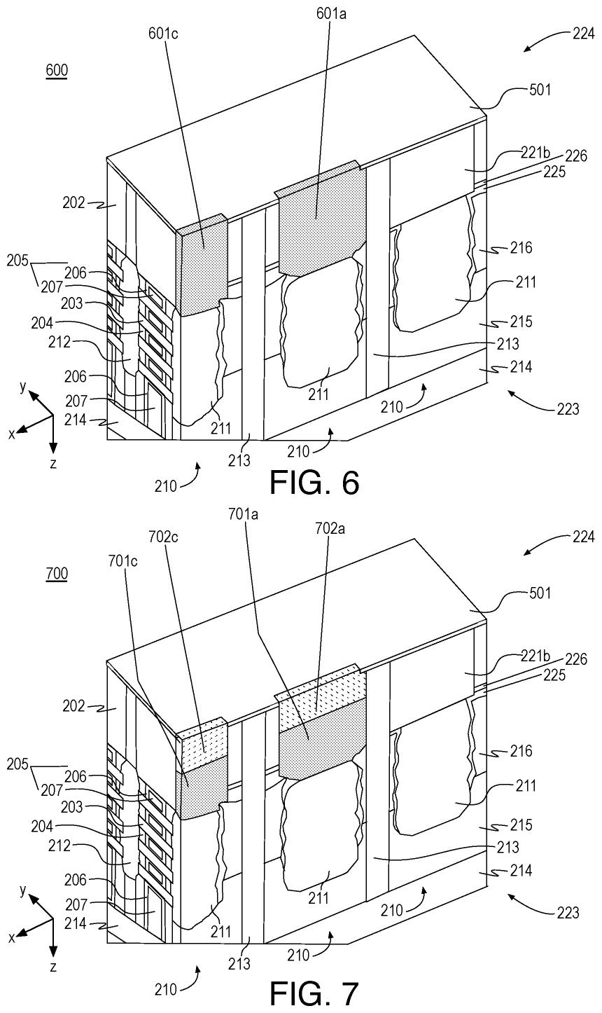

FIG. 6 is an isometric view of a transistor structure 600 similar to transistor structure 500 after formation of contact metals 601a, 601c. In addition to the bulk material of contact metals 601a, 601c, contact metals 601a, 601c may include a silicide layer or other chemical compound layer (not shown) formed on backside surfaces of source structures 211 and/or drain structures 212 prior to formation of the bulk material of contact metals 601a, 601c. Such materials may reduce the contact resistance to source structures 211 and/or drain structures 212. The silicide layer or other chemical compound layer and contact metals 601a, 601c may be formed using any suitable technique or techniques. For example, the silicide layer or other chemical compound layer may be formed by application of a thin layer (e.g., titanium, nickel, sodium, magnesium, platinum, tungsten, molybdenum, etc.) followed by an anneal process. Subsequently, the fill metal of contact metals 601a, 601c may be deposited and planarized. The fill metal of contact metals 601a, 601c may be any suitable contact metal such as molybdenum, tungsten, cobalt, a combination thereof, or other metal(s).

FIG. 7 is an isometric view of a transistor structure 700 similar to transistor structure 600 after recessing contact metals 601a, 601c to form backside contacts 701a, 701c and after formation of etch stop layers 702a, 702c on and over backside 224 of backside contacts 701a, 701c, respectively. Backside contacts 701a, 701c may be formed using any suitable technique or techniques such as recessing of contact metals 601a, 601c using, for example, etch processing. As discussed, backside contacts 701a, 701c may include a silicide layer or other compound layer. The silicide layer or other compound layer may include one or more materials of source structures 211 and/or drain structures 212 and an electropositive element such as titanium, nickel, sodium, magnesium, platinum, tungsten, molybdenum, etc. for reduced contact resistance. Backside contacts 701a, 701c include a contact metal on the silicide layer or other compound layer or directly on source structures 211 and/or drain structures 212. The contact metal may be any suitable metal such as molybdenum, tungsten, cobalt, or a combination thereof.

Etch stop layers 702a, 702c are on and over backside contacts 701a, 701c, and etch stop layers 702a, 702c will selectively protect backside contacts 701a, 701c from being landed on by incorrect backside metallization structures during lithography and etch processing, as is discussed further herein below. Etch stop layers 702a, 702c may be formed using any suitable technique or techniques. In some embodiments, etch stop layers 702a, 702c are deposited as a bulk material and then planarized. Etch stop layers 702a, 702c may be any suitable material or materials. In some embodiments, etch stop layers 702a, 702c are silicon nitride layers or materials (e.g., a material including silicon and nitrogen). In some embodiments, etch stop layers 702a, 702c are silicon oxynitride layers or materials (e.g., a material including silicon, oxygen, and nitrogen). In some embodiments, etch stop layers 702a, 702c are silicon carbide layers or materials (e.g., a material including silicon and carbon). Advantageously, etch stop layers 702a, 702c are dielectric materials to reduce the risk of shorting. Therefore, etch stop layers 702a, 702c may be characterized as dielectric layers or as dielectric materials.

Notably, the material of etch stop layers 702a, 702c advantageously has an etch selectivity with respect to subsequently formed etch stop layers on a second set of backside contacts. For example, when etch stop layers 702a, 702c are silicon nitride or silicon oxynitride, the etch stop layers formed on the second set of backside contacts may be silicon carbide. And, when etch stop layers 702a, 702c are silicon carbide, the etch stop layers formed on the second set of backside contacts may be silicon nitride or silicon oxynitride. Other combinations of etch selective materials are available. The material of etch stop layers 702a, 702c may further have an etch selectivity with respect to dielectric layer 202 and/or isolation dielectric structures 213. For example, dielectric layer 202 and/or isolation dielectric structures 213 may be silicon oxide. In some embodiments, dielectric layer 202 and isolation dielectric structures 213 are silicon oxide, etch stop layers 702a, 702c are one of silicon nitride or silicon oxynitride, and the etch stop layers formed on the second set of backside contacts are silicon carbide. In some embodiments, dielectric layer 202 and isolation dielectric structures 213 are silicon oxide, etch stop layers 702a, 702c are silicon carbide and the etch stop layers formed on the second set of backside contacts are one of silicon nitride or silicon oxynitride.

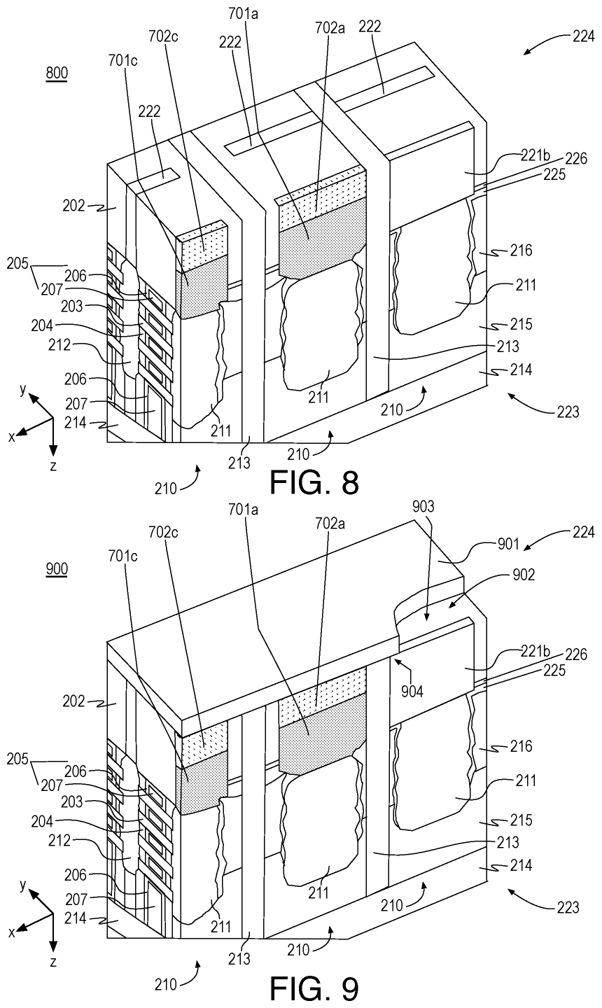

FIG. 8 is an isometric view of a transistor structure 800 similar to transistor structure 700 after removal of protective layer 501. Protective layer 501 may be removed using any suitable technique or techniques such as planarization or polish techniques. As shown, removal of protective layer 501 reveals backside dummy contact structures 221b, 222. For example, backside dummy contact structure 221b may be a part of a second subset of dummy contact structures to be colored with a different etch stop material, while dummy contact structures 222 may ultimately be removed. Therefore, in backside processing according to the present techniques, backside accessible dummy contact structures may be divided into three subsets for processing, two of which are colored with different etch stop layers such that immediately adjacent ones of the backside accessible dummy contact structures may be colored differently for etch selectively, and one of which is removed. Furthermore, removal of protective layer 1101 may reduce a z-height of etch stop layers 702a, 702c.

Returning to FIG. 1, processing continues at operation 105, where a second subset of the backside dummy contacts are selectively exposed while the first subset of backside contacts/first etch stop layers are selectively covered or obscured by a patterned material layer. The patterned layer may be formed using any suitable technique or techniques such as lithographic techniques. For example, a resist layer, a hardmask layer, a multiple layer hardmask, or the like may be deposited and patterned using any suitable technique or techniques such as lithography or lithography and etch.

FIG. 9 is an isometric view of a transistor structure 900 similar to transistor structure 800 after formation of patterned layer 901. Patterned layer 901 may be a resist layer, a hardmask layer, a multiple layer hardmask, or other suitable patterning material. Patterned layer 901 may be formed deposition and lithography operations. As shown, patterned layer 901 includes one or more openings 902 that expose a second subset of backside dummy contact structures including backside dummy contact structure 221b while covering etch stop layers 702a, 702c and backside contacts 701a, 701c. As discussed, etch stop layers 702a, 702c and backside contacts 701a, 701c replaced a first subset of backside dummy contact structures. Again, due to the etch selectivity of backside dummy contact structures 221b relative to other exposed materials, opening 902 does not need to perfectly align with backside dummy contact structure 221b. As shown with respect to exposure 903, portions of dielectric layer 202 and/or isolation dielectric structures 213 may be exposed by opening 902 and, as shown with respect to overlap 904, not all of top surfaces of backside dummy contact structure 221b need to be fully exposed to fully remove backside dummy contact structure 221b during subsequent etch processing.

Returning to FIG. 1, processing continues at operation 106, where the exposed second subset of the backside dummy contacts are selectively removed and replaced with a material stack including a backside contact (e.g., metal contact) on the source or drain exposed by removal of the backside dummy contact and a second etch stop material on the backside contact, such that the second etch stop material has an etch selectivity with respect to the first etch stop material applied at operation 104. Notably, the first and second etch stop materials provide etch selectivity when opening the underlying backside contacts (e.g., metal contacts) for selective connection of backside metallization structures.

The exposed second subset of backside dummy contacts may be removed using any suitable technique or techniques such as selective isotropic etch processing including wet etch processes. The contact metal and second etch stop material may be formed using any suitable technique or techniques. In some embodiments, a protective layer is formed on lateral surfaces but not within the openings defined by the removal of the second subset of the backside dummy contacts (which have a high aspect ratio). The contact metal may then be deposited in the openings and planarized, followed by recess of the contact metal, deposition of the second etch stop material and planarization processing of the second etch stop material.

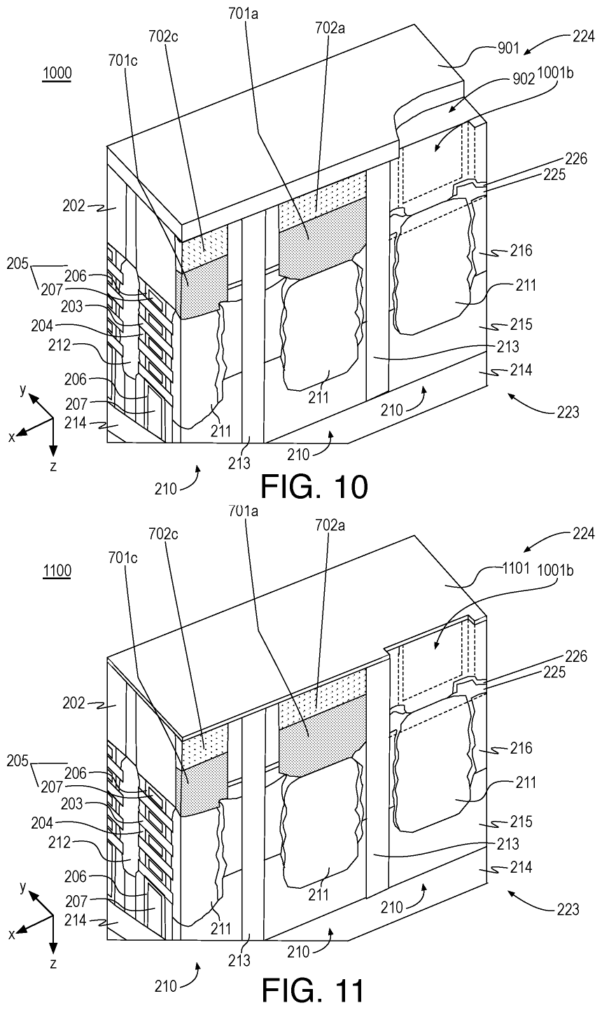

FIG. 10 is an isometric view of a transistor structure 1000 similar to transistor structure 900 after a selective isotropic etch removes backside dummy contact structures including backside dummy contact structure 221b to form openings including opening 1001b. The selective isotropic etch may be any suitable etch process that is selective to the material of backside dummy contact structures 221a, 221c such as an isotropic wet etch process. Due to the selective nature of the etch process, backside dummy contact structure 221b is removed while other structures remain such that, opening 902 does not need to perfectly align with backside dummy contact structure 221b for effective etch out of backside dummy contact structure 221b. Notably, the selective isotropic etch exposes backside surfaces of source structures 211 and/or drain structures 212 associated with the second subset of backside dummy contact structures such as backside dummy contact structure 221b.

FIG. 11 is an isometric view of a transistor structure 1100 similar to transistor structure 1000 after removal of patterned layer 901, and formation of a protective layer 1101. Patterned layer 901 may be removed using any suitable technique or techniques such as dry and/or wet etch techniques. For example, patterned layer 901 may be removed using ashing techniques. Protective layer 1101 aids in the formation of a contact metal and second etch stop material layer in openings such as opening 1001b. Protective layer 1101 may be formed using any suitable technique or techniques such as sputter deposition techniques that provide protective layer 1101 deposition only on a top or backside surface while no deposition occurs opening 1001b due to the high aspect ratio of opening 1001b. Protective layer 1101 may be any suitable protective material such as titanium nitride (e.g., a layer including titanium and nitrogen), silicon, titanium oxide (e.g., a layer including titanium and oxygen), aluminum nitride (e.g., a layer including aluminum and nitrogen), or others. Protective layer 1101 and protective layer 501 may use the same materials or they may be different.

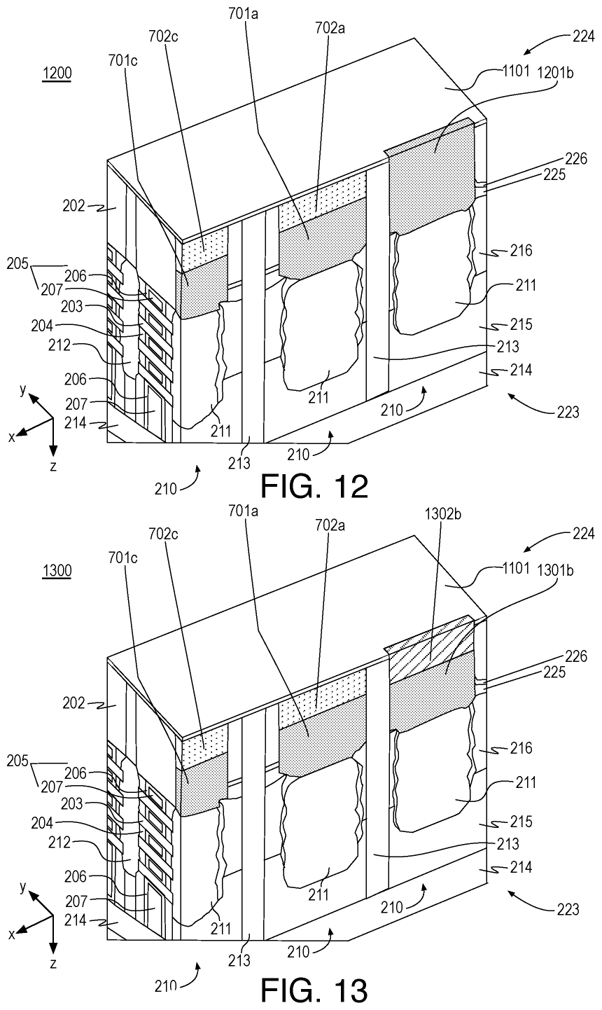

FIG. 12 is an isometric view of a transistor structure 1200 similar to transistor structure 1100 after formation of contact metals including contact metal 1201b. In addition to the bulk material of contact metal 1201b, contact metal 1201b may include a silicide layer or other chemical compound layer (not shown) formed on backside surfaces of source structures 211 and/or drain structures 212 prior to formation of the bulk material of contact metal 1201b. The silicide layer or other chemical compound layer and contact metal 1201b may be formed using any suitable technique or techniques. For example, the silicide layer or other chemical compound layer may be formed by application of a thin layer (e.g., titanium, nickel, sodium, magnesium, platinum, tungsten, molybdenum, etc.) followed by an anneal process. Subsequently, the fill metal of contact metal 1201b may be deposited and planarized. The fill metal of contact metal 1201b may be any suitable contact metal such as molybdenum, tungsten, cobalt, a combination thereof, or other metal(s). The silicide or other chemical compound layer and/or the fill metal of contact metal 1201b may be the same as those applied with respect to contact metals 601a, 601c or one or both may be different.

FIG. 13 is an isometric view of a transistor structure 1300 similar to transistor structure 1200 after recessing contact metals including contact metal 1201b to form backside contacts including backside contact 1301b, and after formation of second etch stop layers including etch stop layer 1302 on and over backside 224 of the backside contacts including backside contact 1301b. Backside contact 1301b may be formed using any suitable technique or techniques such as recessing of contact metal 1201b using, for example, etch processing. As discussed, backside contact 1301b may include a silicide layer or other compound layer. The silicide layer or other compound layer may include one or more materials of source structures 211 and/or drain structures 212 and an electropositive element such as titanium, nickel, sodium, magnesium, platinum, tungsten, molybdenum, etc. for reduced contact resistance. Backside contact 1301b includes a contact metal on the silicide layer or other compound layer or directly on source structures 211 and/or drain structures 212. The contact metal may be any suitable metal such as molybdenum, tungsten, cobalt, or a combination thereof.

Etch stop layer 1302b is on and over backside contact 1301b, and etch stop layer 1302b will selectively protect backside contact 1301b from being landed on by incorrect backside metallization structures. Etch stop layer 1302b may be formed using any suitable technique or techniques such as deposition as a bulk material followed by planarization. Etch stop layer 1302b may be any suitable material or materials. In some embodiments, etch stop layer 1302b is a silicon nitride layer or material (e.g., a material including silicon and nitrogen). In some embodiments, layer 1302b is a silicon oxynitride layer or material (e.g., a material including silicon, oxygen, and nitrogen). In some embodiments, layer 1302b is a silicon carbide layer or material (e.g., a material including silicon and carbon). Advantageously, layer 1302b is a dielectric material and layer 1302b may be characterized as a dielectric layer or as a dielectric material.

Notably, the material of etch stop layer 1302b has an etch selectivity with respect to the material of etch stop layers 702a, 702c. In some embodiments, etch stop layers 702a, 702c are silicon nitride or silicon oxynitride, and etch stop layer 1302b is silicon carbide. In some embodiments, etch stop layers 702a, 702c are silicon carbide, and etch stop layer 1302b is silicon nitride or silicon oxynitride. Other combinations of etch selective materials may be used. The material of etch stop layer 1302b may further have an etch selectivity with respect to dielectric layer 202 and/or isolation dielectric structures 213, as discussed with respect to etch stop layers 702a, 702c. In some embodiments, dielectric layer 202 and/or isolation dielectric structures 213 may be silicon oxide. In some embodiments, dielectric layer 202 and isolation dielectric structures 213 are silicon oxide, etch stop layers 702a, 702c are one of silicon nitride or silicon oxynitride, and etch stop layer 1302b is silicon carbide. In some embodiments, dielectric layer 202 and isolation dielectric structures 213 are silicon oxide, etch stop layers 702a, 702c are silicon carbide, etch stop layer 1302b is one of silicon nitride or silicon oxynitride.

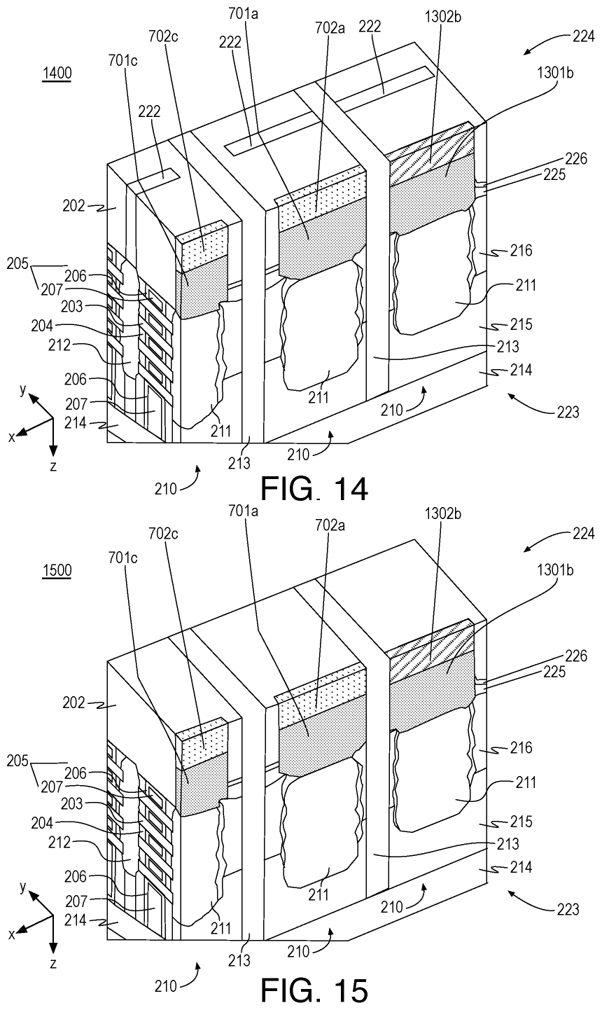

FIG. 14 is an isometric view of a transistor structure 1400 similar to transistor structure 1300 after removal of protective layer 1101. Protective layer 1101 may be removed using any suitable technique or techniques such as planarization or polish techniques. As shown, removal of protective layer 1101 reveals dummy contact structures 222. Furthermore, removal of protective layer 1101 may reduce a z-height of etch stop layer 1302b. As shown, etch stop layer 1302b and etch stop layers 702a, 702c are substantially coplanar such that they have top and bottom surfaces that are substantially coplanar in the x-y plane. Similarly, backside contact 1301b and backside contacts 701a, 701c are also substantially coplanar such that they have top and bottom surfaces that are substantially coplanar in the x-y plane.

FIG. 15 is an isometric view of a transistor structure 1500 similar to transistor structure 1400 after removal of dummy contact structures 222 and backfill with dielectric material or dielectric layer 202. Dummy contact structures 222 may be removed using any suitable technique or techniques such as selective etch techniques. The backfill with dielectric material or dielectric layer 202 may include a bulk deposition of dielectric material such as silicon oxide (e.g., a material including silicon and oxygen) followed by planarization. However, other dielectric materials may be used.

Transistor structure 1500 has etch stop layer 1302b and etch stop layers 702a, 702c, which may also be characterized as dielectric layers or dielectric materials, such that etch stop layer 1302b and etch stop layers 702a, 702c are different materials. Such material difference and, in particular, etch selectivity between etch stop layer 1302b and etch stop layers 702a, 702c due to the material difference may be exploited to more reliably land metallization structures on underlying backside contacts 1301b and backside contacts 701a, 701c. The metallization structures are formed in two process passes such that a first subset of metallization structures are first formed on a first subset having the first etch stop layer type (e.g., backside contact 1301b), and a second subset of metallization structures are then formed on a second subset having the second etch stop layer type (e.g., backside contacts 701a, 701c). During the processing to expose backside contact 1301b, for example, a selective anisotropic etch process used. As illustrated further below, if etch stop layers 702a, 702c are exposed during the selective anisotropic etch process (e.g., due to lithographic misalignment), etch stop layers 702a, 702c protect the underlying backside contacts 701a, 701c. Therefore, are backside contacts 701a, 701c not exposed, and no metallization structure is formed on them, which would be the case if differing etch stop layer 1302b and etch stop layers 702a, 702c were not deployed. In some embodiments, such advantages extend to the second process pass, however, this depends on the nature of the first process pass, as is discussed below.

Returning to FIG. 1, processing continues at operation 107, where backside metallization structures are selectively formed on the backside contacts covered by a first etch stop layer, and not on backside contacts covered by a first etch stop layer. Such backside metallization structures may be formed using any suitable technique or techniques. In some embodiments, a dielectric layer is first formed over the backside of the workpiece, such that backside metallization structures are to be embedded in the dielectric layer. A patterned layer is then formed over the dielectric layer such that the patterned layer has openings corresponding to the first subset of backside metallization structures that are to be formed. Ideally, the patterned layer includes openings to land the backside metallization structures on the underlying backside contacts with no error. However, ideal patterning cannot be expected, and backside distortion and other issues cause misalignment and imperfect patterning. When the opening inadvertently exposes underlying backside contacts that are not intended to be landed on, those underlying backside contacts are covered by the second etch stop layer.

During subsequent selective etch, the etchant chemistry and conditions apply an anisotropic etch that is selective to remove the first etch stop layer while leaving the second etch stop layer substantially unaffected. This protects the underlying backside contacts that are not intended to be landed on, keeping them obscured and covered by dielectric material. the backside metallization structures are then formed using any suitable technique or techniques such as damascene or dual damascene processes within the opening in the dielectric layer. Again, during this processing, any attempt to land on the second subset of backside contacts is avoided by the discussed etch selectivity.

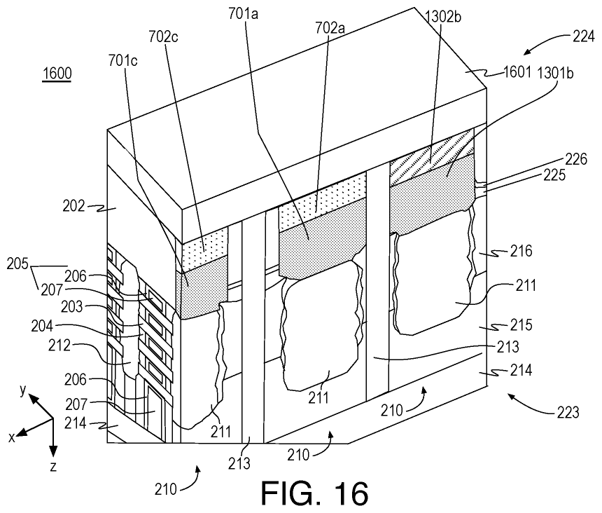

FIG. 16 is an isometric view of a transistor structure 1600 similar to transistor structure 1500 after application of a dielectric layer 1601. Dielectric layer 1601 may be formed using any suitable technique or techniques such as deposition followed by planarization. In some embodiments, dielectric layer is or includes silicon oxide (e.g., a material including silicon and oxygen). However, other dielectric materials may be used.

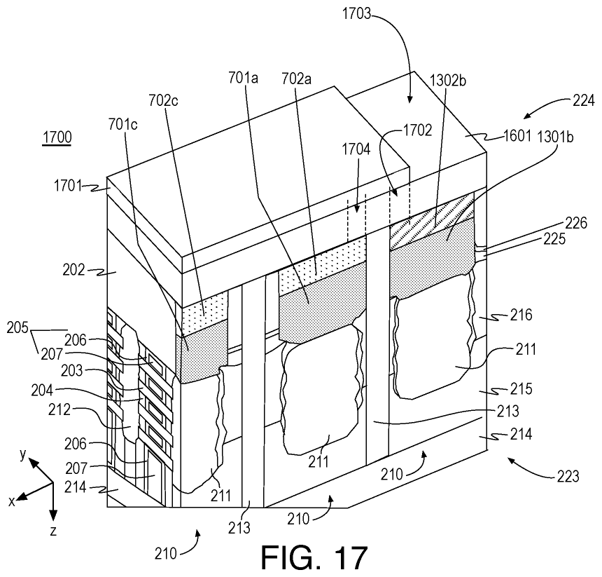

FIG. 17 is an isometric view of a transistor structure 1700 similar to transistor structure 1600 after formation of a patterned layer 1701 over dielectric layer 1601. Patterned layer 1701 may be a resist layer, a hardmask layer, a multiple layer hardmask, or other suitable patterning material. Patterned layer 1701 may be formed using any suitable technique or techniques such as deposition and lithography operations. As shown, patterned layer 1701 includes one or more openings 1703 that define where subsequent metallization structures or features will land on underlying structures. In this case, it is desirable for a metallization structure or feature to land on backside contact 1301b. Of course, landing the metallization structure or feature on backside contact 701a would cause a short or other circuitry error. Notably, an ideal placement of opening 1703 may align an edge of opening 1703 on isolation dielectric structure 213 between backside contacts 701a, 1301b.

In the example of FIG. 17, opening 1703 has a misalignment 1702 (e.g., which is in the negative x-direction) such that a subsequently formed metallization structure or feature will land partially on backside contact 1301b while leaving a portion of etch stop layer 1302b. In other contexts, opening 1703 has a misalignment 1704 in the positive x-direction such that a subsequently formed metallization structure or feature would attempt to land on backside contact 701a while landing on backside contact 1301b. This is the scenario that the etch selectivity between etch stop layer 1302b and etch stop layers 702a, 702c will stop, as the anisotropic etch will selectively not etch etch stop layer 702a. As discussed, in some embodiments, dielectric layers 202, 1601 and isolation dielectric structures 213 are silicon oxide, etch stop layers 702a, 702c are one of silicon nitride or silicon oxynitride, and etch stop layer 1302b is silicon carbide. In some embodiments, dielectric layers 202, 1601 and isolation dielectric structures 213 are silicon oxide, etch stop layers 702a, 702c are silicon carbide, etch stop layer 1302b is one of silicon nitride or silicon oxynitride.

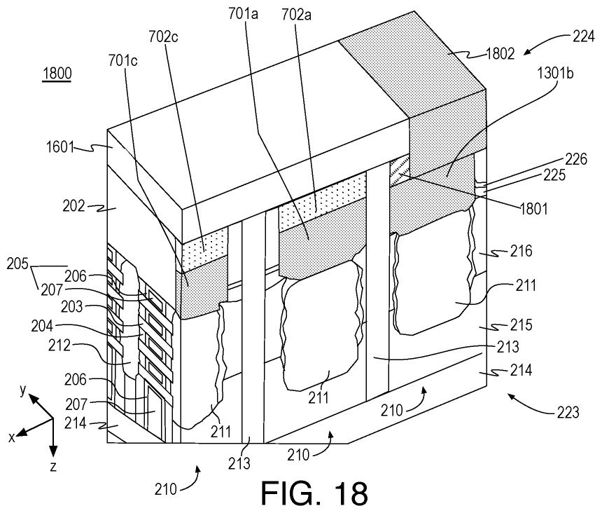

FIG. 18 is an isometric view of a transistor structure 1800 similar to transistor structure 1700 after removal of exposed portions of dielectric layer 1601 and etch stop layer 1302b, and formation of a backside metallization structure 1802 in contact with a backside surface of backside contact 1301b. As shown, misalignment 1702 (refer to FIG. 17) causes a dielectric material 1801 (or etch stop material) to remain on a portion of the backside surface of backside contact 1301b. The portions of dielectric layer 1601 and etch stop layer 1302b may be removed using any suitable technique or techniques such anisotropic etch techniques. In some embodiments, a single anisotropic etch chemistry is used. In some embodiments, portions of dielectric layer 1601 are anisotropically etched with a first anisotropic etch chemistry and all or a portion of etch stop layer 1302b is removed with a second anisotropic etch chemistry.

In the illustrated example, misalignment 1702 of opening 1703 (refer to FIG. 17) causes backside metallization structure 1802 to land on a portion of backside contact 1301b while dielectric material 1801 is on another portion of backside contact 1301b. Dielectric material 1801 may be any material and may have any characteristics discussed with respect to etch stop layer 1302b. With reference to FIG. 17, it is noted that during the etch of etch stop layer 1302b, misalignment 1704 would not cause backside metallization structure 1802 to land on backside contact 701a. Instead, a portion of etch stop layer 702a would be between backside metallization structure 1802 and backside contact 701a.

After removal of portions of dielectric layer 1601 and etch stop layer 1302b, patterned layer 1701 (refer to FIG. 17) is removed using any suitable technique or techniques such as dry and/or wet etch techniques. For example, patterned layer 1701 may be removed using ashing techniques. Backside metallization structure 1802 is then formed using techniques known in the art. In some embodiments, a conductive layer is first applied (e.g., a titanium- or tantalum-based layer). This layer may provide adhesion for the subsequent bulk metal and a barrier to prevent diffusion of the subsequent bulk metal. After application of the conductive layer, the bulk metal of backside metallization structure 1802 is then deposited and planarized to form backside metallization structure 1802, which includes the conductive layer and the bulk metal. The bulk metal may be any suitable conductor such as copper.

Returning to FIG. 1, processing continues at operation 108, where backside metallization structures are selectively formed on the backside contacts covered by the second etch stop layer, and not on backside contacts previously covered by the first etch stop layer. Notably, the backside contacts previously covered by the first etch stop layer may have had the first etch stop layer or a portion of the first etch stop layer may remain. The backside metallization structures fabricated at operation 108 may be formed using any suitable technique or techniques. In some embodiments, a patterned layer is then formed over the dielectric layer and metallization structures fabricated at operation107. The patterned layer has openings corresponding to the second subset of backside metallization structures that are to be formed. Ideally, openings of the patterned layer would land the backside metallization structures on the underlying backside contacts with no error. However, when the opening inadvertently exposes underlying backside contacts that are not intended to be landed on, the discussed backside contact coloring process flow may provide those underlying backside contacts with the first etch stop layer.

During subsequent selective etch, the etchant chemistry and conditions apply an anisotropic etch that is selective to remove the second etch stop layer while leaving the first etch stop layer substantially unaffected. This may protect the underlying backside contacts that are not intended to be landed on, as discussed with respect to operation 107. the backside metallization structures are then formed using any suitable technique or techniques such as damascene or dual damascene processes within the opening in the dielectric layer. During such backside metallization structure formation this processing, any attempt to land on the first subset of backside contacts may be avoided in some contexts due to the discussed etch selectivity.

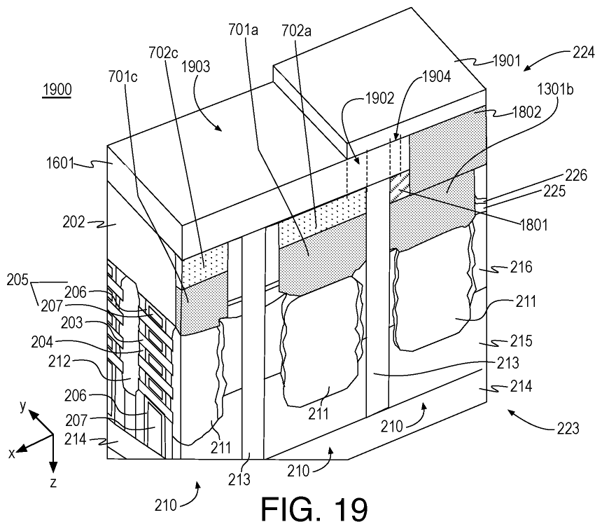

FIG. 19 is an isometric view of a transistor structure 1900 similar to transistor structure 1800 after formation of a patterned layer 1901 over dielectric layer 1601 and backside metallization structure 1802. Patterned layer 1901 may be formed using any suitable technique or techniques such as deposition and lithography operations, and patterned layer 1901 may be a resist layer, a hardmask layer, a multiple layer hardmask, or other suitable patterning material. As shown, patterned layer 1901 includes one or more openings 1903 that define where subsequent metallization structures or features will land on underlying structures. In this case, it is desirable for a metallization structure or feature to land on backside contacts 701a, 701c, and undesirable for the metallization structure or feature to land on backside contact 1301b or to contact backside metallization structure 1802 with an ideal placement of opening 1903 again aligning an edge of opening 1903 on isolation dielectric structure 213 between backside contacts 701a, 1301b.

In FIG. 19, opening 1903 has a misalignment 1902 (e.g., which is in the positive x-direction) such that a subsequently formed metallization structure or feature will land partially on backside contact 701a while leaving a portion of etch stop layer 702a. In other contexts, opening 1903 has a misalignment 1904 in the negative x-direction such that a subsequently formed metallization structure or feature would attempt to land on backside contact 1301b. In this context, the etch selectivity between etch stop layers 702a, 702c and dielectric material 1801 will stop the etch and not allow such metallization structure contact. It is noted that the techniques discussed herein cannot prevent all lithographic misalignments as, in this context, misalignment 1904 may extend all the way to backside metallization structure 1802. However, the backside contact coloring flow techniques discussed herein widen the allowable lithographic and etch distortions and errors, and enable continual shrinking of transistors, transistor cell sizes, contact structures, and so on.

FIG. 20 is an isometric view of a transistor structure 2000 similar to transistor structure 1900 after removal of exposed portions of dielectric layer 1601 and etch stop layers 702a, 702c, and formation of a backside metallization structure 2002 in contact with backside surfaces of backside contacts 701a, 701c. As shown, misalignment 1902 (refer to FIG. 19) causes a dielectric material 2001 (or etch stop material) to remain on a portion of a backside surface of backside contact 701a. The portions of dielectric layer 1601 and etch stop layers 702a, 702c may be removed using any suitable technique or techniques such anisotropic etch techniques. In some embodiments, a single anisotropic etch chemistry is used. In some embodiments, portions of dielectric layer 1601 are anisotropically etched with a first anisotropic etch chemistry and all or portions of etch stop layers 702a, 702c are removed with a second anisotropic etch chemistry.

In the illustrated example, misalignment 1902 of opening 1903 (refer to FIG. 19) causes backside metallization structure 2002 to land on all of backside contact 701c and a portion of backside contact 701a while dielectric material 2001 is on another portion of backside contact 701a. Dielectric material 2001 may be any material and may have any characteristics discussed with respect to etch stop layers 702a, 702c. Notably, with reference to FIG. 19, during the etch of etch stop layer 702a, misalignment 1904 would not cause backside metallization structure 2002 to land on backside contact 1301b. Instead, a portion of dielectric material 1801 (e.g., the first etch stop material) would be between backside metallization structure 2002 and backside contact 1301b.

After removal of portions of dielectric layer 1601 and all or portions of etch stop layers 702a, 702c, patterned layer 1901 (refer to FIG. 17) is removed using any suitable technique or techniques such as dry and/or wet etch techniques, inclusive of ashing techniques. Backside metallization structure 2002 is then formed using techniques known in the art. In some embodiments, a conductive layer is first applied (e.g., a titanium- or tantalum-based layer), followed by deposition of the bulk metal of backside metallization structure 2002 (e.g., copper) and planarization processing to form backside metallization structure 2002. Backside metallization structure 2002 includes the conductive layer and the bulk metal. Backside metallization structure 2002 and backside metallization structure 1802 may be the same materials or they may be different.

As shown in FIG. 20, transistor structure 2000 includes transistor 210 including semiconductor structure 203 extending between source structure 211 and drain structure 212, and gate structure 205 over a channel region 2018 of semiconductor structure 203 (e.g., the portion of semiconductor structure 203 controllable by gate structure 205). Backside contact 701a is on source structure 211 (though it could be on drain structure 212) and isolation dielectric structure 213 (e.g., a dielectric material) separates backside contact 701a from backside contact 1301b. Dielectric material 2001 is on a backside surface 2011 of backside contact 701a and on a side or sidewall 2013 of isolation dielectric structure 213. Dielectric material 1801 is on a backside surface 2012 of backside contact 1301b and on a side or sidewall 2014 of isolation dielectric structure 213 opposite sidewall 2013. Furthermore, backside metallization structure 2002 is on backside surface 2011 of backside contact 701a and on a sidewall 2015 of dielectric material 2001, and backside metallization structure 1802 is on backside surface 2012 of backside contact 1301b and on a sidewall 2016 of dielectric material 1801. Also as shown, dielectric layer 1601 (e.g., a dielectric material) is on dielectric material 2001, dielectric material 1801, isolation dielectric structure 213, backside metallization structure 2002, and backside metallization structure 1802.

Transistor structure 2000 may have any suitable dimensions. In some embodiments, backside metallization structures 1802, 2002 have a pitch of not more than 100 nm, and one or both of dielectric materials 1801, 2001 have a lateral width of not more than 10 nm. As used herein, the term pitch indicates a minimum dimension taken between like features and the term lateral width indicates a width taken in the x-y plane. For example, the lateral width and the pitch may both be in the x-dimension in FIG. 20. In some embodiments, dielectric material 2001 and dielectric material 1801 are coplanar dielectric material 2001 and dielectric material 1801 are aligned in the x-y plane.

Returning to FIG. 1, processing continues at operation 109, where any number of levels of backside metallization are formed over the discussed backside contacts and backside metallization structures, and opposite the frontside metallization layers with respect to the transistor or device layer. As discussed, a partially fabricated workpiece is mounted, by its frontside, to a carrier such as a carrier wafer, and a backside contact coloring flow process forms backside contacts and backside metallization structure. Additional backside metallization layers are then fabricated over the. The backside metallization layers may be formed using any suitable technique or techniques such as dual damascene techniques, single damascene techniques, subtractive metallization patterning techniques, or the like. For example, power-delivery may be provided by the backside metallization layers. Although discussed with respect to power delivery, interconnectivity, signal routing, a ground plane, or other functionalities may be provided by the backside metallization layers.

Processing continues at operation 110, where the carrier attached at operation 102 may be removed, and at operation 111, where continued processing is performed as is known in the art to dice, package, and output an integrated circuit (IC) die, package, or device including the discussed features. At operation 110, the carrier may be removed using any suitable technique or techniques such as delamination, UV curing, or the like. At operation 111, the continued processing may include dicing, packaging, assembly, and so on. The resultant device (e.g., IC die, IC package, IC assembly, etc.) may then be implemented in any suitable form factor device such as a laptop, a netbook, a notebook, an ultrabook, a smartphone, a tablet, a personal digital assistant, an ultra-mobile PC, a mobile phone, a desktop computer, a server, a printer, a scanner, a monitor, a set-top box, an entertainment control unit, a digital camera, a portable music player, a digital video recorder, or the like.

FIG. 21 illustrates a cross-sectional side view of an integrated circuit device structure 2100 similar to transistor structure 2000 after incorporation of transistor structure 2000 into an integrated circuit die 2116, arranged in accordance with some embodiments of the disclosure. As shown, any number of frontside metallization layers 231 may be formed over transistor structure 2000. For example, interconnectivity, signal routing, optional power-delivery, and the like may be provided by frontside metallization layers 231. As used herein, the term metallization layer indicates metal interconnections or wires that provide electrical routing. Adjacent metallization layers, such as metallization layer 2102, are interconnected by vias, such as via 2103, that may be characterized as part of the metallization layers or between the metallization layers. As shown, in some embodiments, frontside metallization layers 231 are formed over and immediately adjacent transistor structure 2000. In the illustrated example, frontside metallization layers 231 include M0, V0, M1, M2/V1, M3/V2, and M4/V3. However, frontside metallization layers 231 may include any number of metallization layers such as eight, ten, twelve, or more metallization layers.

Furthermore, backside metallization layers 2110, including backside metallization structure 2002, for example, may be formed under transistor structure 2000. For example, power-deliver, optional additional interconnectivity, and routing to outside devices (not shown) may be provided by backside metallization layers 2110. As shown, in some embodiments, backside metallization layers 2110 are formed over and immediately adjacent transistor structure 2000. In the illustrated example, backside metallization layers 2110 include BM0, BM1, and BM2 with intervening via layers. However, backside metallization layers 2110 may include any number of metallization layers such as three, four, or more metallization layers. In the illustrated example, package level interconnects 2118 are provided on or under backside 224 as bumps over a passivation layer 2115. However, package level interconnects 2118 may be provided using any suitable interconnect structures such as bond pads, solder bumps, etc. In some embodiments, integrated circuit die 2116 includes any transistor structure discussed herein, and integrated circuit die 2116 is coupled to a power supply/battery 2125, which may be any suitable power supply device or component. In addition or in the alterative, integrated circuit die 2116 may couple to other devices such as a display, a peripheral device, or the like. For example, integrated circuit die 2116 may couple to any component discussed herein below.

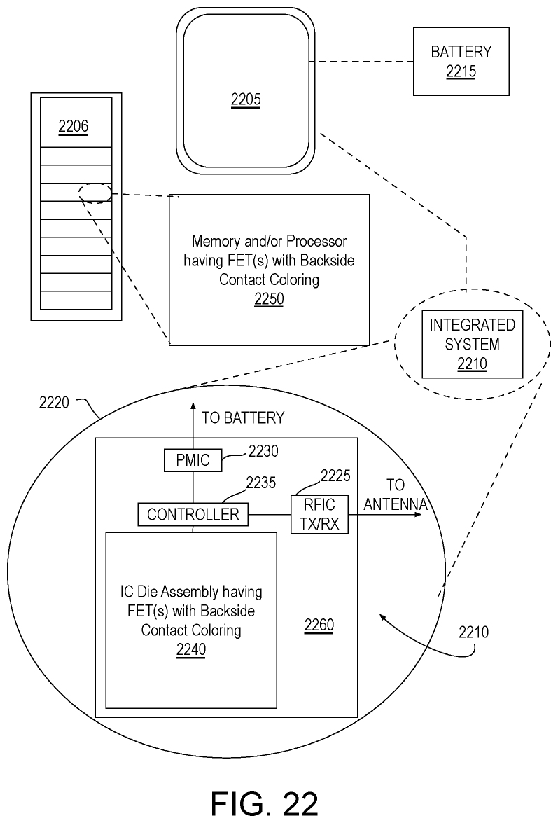

FIG. 22 illustrates exemplary systems employing transistor structures having field effect transistors with backside contact coloring, in accordance with some embodiments. The system may be a mobile computing platform 2205 and/or a data server machine 2206, for example. Either may employ a monolithic IC die, for example, having field effect transistors with backside contact coloring as described elsewhere herein. Server machine 2206 may be any commercial server, for example including any number of high-performance computing platforms disposed within a rack and networked together for electronic data processing, which in the exemplary embodiment includes an IC die assembly 2250 having field effect transistors with backside contact coloring as described elsewhere herein. Mobile computing platform 2205 may be any portable device configured for each of electronic data display, electronic data processing, wireless electronic data transmission, or the like. For example, mobile computing platform 2205 may be any of a tablet, a smart phone, a laptop computer, etc., and may include a display screen (e.g., a capacitive, inductive, resistive, or optical touchscreen), a chip-level or package-level integrated system 2210, and a battery/power supply 2215. Although illustrated with respect to mobile computing platform 2205, in other examples, chip-level or package-level integrated system 2210 and a battery/power supply 2215 may be implemented in a desktop computing platform, an automotive computing platform, an internet of things platform, or the like. As discussed below, in some examples, the disclosed systems may include a sub-system 2260 such as a system on a chip (SOC) or an integrated system of multiple ICs, which is illustrated with respect to mobile computing platform 2205.

Whether disposed within integrated system 2210 illustrated in expanded view 2220 or as a stand-alone packaged device within data server machine 2206, sub-system 2260 may include memory circuitry and/or processor circuitry 2240 (e.g., RAM, a microprocessor, a multi-core microprocessor, graphics processor, etc.), a power management integrated circuit (PMIC) 2230, a controller 2235, and a radio frequency integrated circuit (RFIC) 2225 (e.g., including a wideband RF transmitter and/or receiver (TX/RX)). As shown, one or more IC dice, such as memory circuitry and/or processor circuitry 2240 may be assembled and implemented such that one or more have field effect transistors with backside contact coloring as described herein. In some embodiments, RFIC 2225 includes a digital baseband and an analog front end module further comprising a power amplifier on a transmit path and a low noise amplifier on a receive path). Functionally, PMIC 2230 may perform battery power regulation, DC-to-DC conversion, etc., and so has an input coupled to battery/power supply 2215, and an output providing a current supply to other functional modules. As further illustrated in FIG. 22, in the exemplary embodiment, RFIC 2225 has an output coupled to an antenna (not shown) to implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. Memory circuitry and/or processor circuitry 2240 may provide memory functionality for sub-system 2260, high level control, data processing and the like for sub-system 2260. In alternative implementations, each of the SOC modules may be integrated onto separate ICs coupled to a package substrate, interposer, or board.

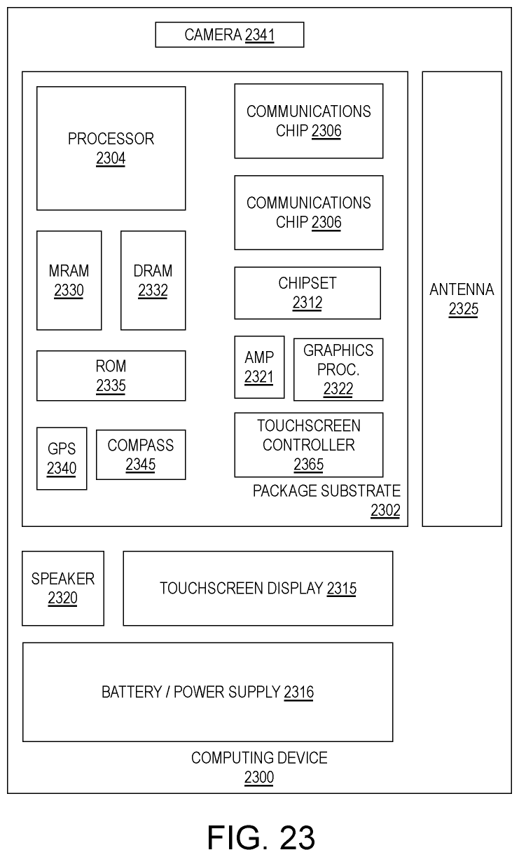

FIG. 23 is a functional block diagram of an electronic computing device 2300, in accordance with some embodiments. For example, device 2300 may, via any suitable component therein, implement field effect transistors with backside contact coloring as discussed herein. For example, one or more IC dies of electronic computing device 2300 may deploy field effect transistors with backside contact coloring. Device 2300 further includes a motherboard or package substrate 2302 hosting a number of components, such as, but not limited to, a processor 2304 (e.g., an applications processor). Processor 2304 may be physically and/or electrically coupled to package substrate 2302. In some examples, processor 2304 is within an IC assembly. In general, the term “processor” or “microprocessor” may refer to any device or portion of a device that processes electronic data from registers and/or memory to transform that electronic data into other electronic data that may be further stored in registers and/or memory.

In various examples, one or more communication chips 2306 may also be physically and/or electrically coupled to the package substrate 2302. In further implementations, communication chips 2306 may be part of processor 2304. Depending on its applications, computing device 2300 may include other components that may or may not be physically and electrically coupled to package substrate 2302. These other components include, but are not limited to, volatile memory (e.g., DRAM 2332), non-volatile memory (e.g., ROM 2335), flash memory (e.g., NAND or NOR), magnetic memory (MRAM 2330), a graphics processor 2322, a digital signal processor, a crypto processor, a chipset 2312, an antenna 2325, touchscreen display 2315, touchscreen controller 2365, battery/power supply 2316, audio codec, video codec, power amplifier 2321, global positioning system (GPS) device 2340, compass 2345, accelerometer, gyroscope, speaker 2320, camera 2341, and mass storage device (such as hard disk drive, solid-state drive (SSD), compact disk (CD), digital versatile disk (DVD), and so forth, or the like.

Communication chips 2306 may enable wireless communications for the transfer of data to and from the computing device 2300. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. Communication chips 2306 may implement any of a number of wireless standards or protocols, including, but not limited to, those described elsewhere herein. As discussed, computing device 2300 may include a plurality of communication chips 2306. For example, a first communication chip may be dedicated to shorter-range wireless communications, such as Wi-Fi and Bluetooth, and a second communication chip may be dedicated to longer-range wireless communications such as GPS, EDGE, GPRS, CDMA, WiMAX, LTE, Ev-DO, and others. Battery/power supply 2316 may include any suitable power supply circuitry and, optionally, a battery source to provide power to components of electronic computing device 2300.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

It will be recognized that the invention is not limited to the embodiments so described but can be practiced with modification and alteration without departing from the scope of the appended claims. For example, the above embodiments may include specific combinations of features as further provided below.

The following pertains to exemplary embodiments.

In one or more first embodiments, an apparatus comprises a transistor comprising a semiconductor structure extending between a source structure and a drain structure, and a gate structure over a channel region of the semiconductor structure, a first backside contact on the source structure or the drain structure, a first dielectric material separating the first backside contact from a second backside contact, a second dielectric material on a backside surface of the first backside contact and a first side of the first dielectric material, and a third dielectric material on a backside surface of the second backside contact and a second side of the first dielectric material opposite the first side.

In one or more second embodiments, further to the first embodiments, the apparatus further comprises a first backside metallization structure on the backside surface of the first backside contact and on a sidewall of the second dielectric material, and a second backside metallization structure on the backside surface of the second backside contact and on a sidewall of the third dielectric material.

In one or more third embodiments, further to the first or second embodiments, the first backside metallization structure and the second backside metallization structure have a pitch of not more than 100 nm, and wherein the second dielectric material has a lateral width of not more than 10 nm.

In one or more fourth embodiments, further to the first through third embodiments, the apparatus further comprises a fourth dielectric material on the first dielectric material, the second dielectric material, the third dielectric material, the first backside metallization structure, and the second backside metallization structure.

In one or more fifth embodiments, further to the first through fourth embodiments, the second dielectric material and the third dielectric material are coplanar.

In one or more sixth embodiments, further to the first through fifth embodiments, the second dielectric material comprises silicon and nitrogen and the third dielectric material comprises silicon and carbon.

In one or more seventh embodiments, further to the first through sixth embodiments, the first dielectric material comprises silicon and oxygen.

In one or more eighth embodiments, further to the first through seventh embodiments, the apparatus further comprises a plurality of frontside metallization layers over the transistor and opposite the first backside contact.

In one or more ninth embodiments, an integrated circuit (IC) die comprises the transistor, the first backside contact, the first dielectric material, the second backside contact, the second dielectric material, and the third dielectric material, and the apparatus or a system comprises the IC die and a power supply coupled to the IC die.

In one or more tenth embodiments, an apparatus comprises a first backside contact on one of a first source structure or a first drain structure of a first transistor, a second backside contact coplanar with the first backside contact and on the other of the first source structure or the first drain structure or on one of a second source structure or a second drain structure of a second transistor, a first dielectric material comprising silicon and oxygen on and between the first backside contact and the second backside contact, a second dielectric material comprising silicon and nitrogen a backside surface of the first backside contact and a first side of the first dielectric material, and a third dielectric material comprising silicon and carbon on a backside surface of the second backside contact and a second side of the first dielectric material opposite the first side.

In one or more eleventh embodiments, further to the tenth embodiments, the apparatus further comprises a first backside metallization structure on the backside surface of the first backside contact and on a sidewall of the second dielectric material, and a second backside metallization structure on the backside surface of the second backside contact and on a sidewall of the third dielectric material.

In one or more twelfth embodiments, further to the tenth or eleventh embodiments, the first backside metallization structure and the second backside metallization structure have a pitch of not more than 100 nm, and wherein the second dielectric material has a lateral width of not more than 10 nm.

In one or more thirteenth embodiments, further to the tenth through twelfth embodiments, the apparatus further comprises a fourth dielectric material on the first dielectric material, the second dielectric material, the third dielectric material, the first backside metallization structure, and the second backside metallization structure.

In one or more fourteenth embodiments, further to the tenth through thirteenth embodiments, an integrated circuit (IC) die comprises the transistor, the first backside contact, the first dielectric material, the second backside contact, the second dielectric material, and the third dielectric material, and the apparatus or a system comprises the IC die and a power supply coupled to the IC die.

In one or more fifteenth embodiments, a method comprises selectively exposing a first backside dummy contact structure, the first backside dummy contact structure in contact with a source structure a drain structure of a transistor, replacing the first backside dummy contact structure with a first backside contact structure and a first etch stop layer on the first backside contact structure, selectively exposing a second backside dummy contact structure, replacing the second backside dummy contact structure with a second backside contact structure and a second etch stop layer on the second backside contact structure, the second etch stop layer having an etch selectivity relative to the first etch stop layer, forming a first backside metallization structure on the first backside contact structure via a first pattern and a first etch selective to the first etch stop layer, and forming a second backside metallization structure on the second backside contact structure via a second pattern and a second etch selective to the second etch stop layer.

In one or more sixteenth embodiments, further to the fifteenth embodiments, the first etch stop layer comprises silicon and nitrogen and the second etch stop layer comprises silicon and carbon.

In one or more seventeenth embodiments, further to the fifteenth or sixteenth embodiments, replacing the first backside dummy contact structure comprises an isotropic etch process, and wherein the first etch comprises an anisotropic etch process.

In one or more eighteenth embodiments, further to the fifteenth through seventeenth embodiments, forming the first backside metallization structure further forms a first dielectric material comprising the first etch stop layer on a backside surface of the first backside contact structure.

In one or more nineteenth embodiments, further to the fifteenth through eighteenth embodiments, forming the second backside metallization structure further forms a second dielectric material comprising the second etch stop layer on a backside surface of the second backside contact structure.

In one or more twentieth embodiments, further to the fifteenth through nineteenth embodiments, the method further comprises removing, subsequent to said replacing the second backside dummy contact structure, a third backside dummy contact structure and backfilling with an isolation material.

It will be recognized that the invention is not limited to the embodiments so described but can be practiced with modification and alteration without departing from the scope of the appended claims. For example, the above embodiments may include specific combination of features. However, the above embodiments are not limited in this regard, and, in various implementations, the above embodiments may include the undertaking only a subset of such features, undertaking a different order of such features, undertaking a different combination of such features, and/or undertaking additional features than those features explicitly listed. The scope of the invention should, therefore, be determined with reference to the appended claims, along with the full scope of equivalents to which such claims are entitled.

What is claimed is:

1. An apparatus, comprising:
a transistor comprising a semiconductor structure extending between a source structure and a drain structure, and a gate structure over a channel region of the semiconductor structure;
a first backside contact on the source structure or the drain structure;
a first dielectric material separating the first backside contact from a second backside contact;
a second dielectric material on a backside surface of the first backside contact and a first side of the first dielectric material; and
a third dielectric material on a backside surface of the second backside contact and a second side of the first dielectric material opposite the first side.

2. The apparatus of claim 1, further comprising:
a first backside metallization structure on the backside surface of the first backside contact and on a sidewall of the second dielectric material; and
a second backside metallization structure on the backside surface of the second backside contact and on a sidewall of the third dielectric material.

3. The apparatus of claim 2, wherein the first backside metallization structure and the second backside metallization structure have a pitch of not more than 100 nm, and wherein the second dielectric material has a lateral width of not more than 10 nm.

4. The apparatus of claim 2, further comprising:
a fourth dielectric material on the first dielectric material, the second dielectric material, the third dielectric material, the first backside metallization structure, and the second backside metallization structure.

5. The apparatus of claim 1, wherein the second dielectric material and the third dielectric material are coplanar.

6. The apparatus of claim 1, wherein the second dielectric material comprises silicon and nitrogen and the third dielectric material comprises silicon and carbon.

7. The apparatus of claim 6, wherein the first dielectric material comprises silicon and oxygen.

8. The apparatus of claim 1, further comprising a plurality of frontside metallization layers over the transistor and opposite the first backside contact.

9. The apparatus of claim 1, wherein an integrated circuit (IC) die comprises the transistor, the first backside contact, the first dielectric material, the second backside contact, the second dielectric material, and the third dielectric material, the apparatus further comprising a power supply coupled to the IC die.

10. An apparatus, comprising:
a first backside contact on one of a first source structure or a first drain structure of a first transistor;
a second backside contact coplanar with the first backside contact and on the other of the first source structure or the first drain structure or on one of a second source structure or a second drain structure of a second transistor;
a first dielectric material comprising silicon and oxygen on and between the first backside contact and the second backside contact;
a second dielectric material comprising silicon and nitrogen a backside surface of the first backside contact and a first side of the first dielectric material; and
a third dielectric material comprising silicon and carbon on a backside surface of the second backside contact and a second side of the first dielectric material opposite the first side.

11. The apparatus of claim 10, further comprising:
a first backside metallization structure on the backside surface of the first backside contact and on a sidewall of the second dielectric material; and
a second backside metallization structure on the backside surface of the second backside contact and on a sidewall of the third dielectric material.

12. The apparatus of claim 11, wherein the first backside metallization structure and the second backside metallization structure have a pitch of not more than 100 nm, and wherein the second dielectric material has a lateral width of not more than 10 nm.

13. The apparatus of claim 11, further comprising:
a fourth dielectric material on the first dielectric material, the second dielectric material, the third dielectric material, the first backside metallization structure, and the second backside metallization structure.

14. The apparatus of claim 10, wherein an integrated circuit (IC) die comprises the transistor, the first backside contact, the first dielectric material, the second backside contact, the second dielectric material, and the third dielectric material, the apparatus further comprising a power supply coupled to the IC die.

15. A method, comprising:
selectively exposing a first backside dummy contact structure, the first backside dummy contact structure in contact with a source structure a drain structure of a transistor;
replacing the first backside dummy contact structure with a first backside contact structure and a first etch stop layer on the first backside contact structure;
selectively exposing a second backside dummy contact structure;
replacing the second backside dummy contact structure with a second backside contact structure and a second etch stop layer on the second backside contact structure, the second etch stop layer having an etch selectivity relative to the first etch stop layer;
forming a first backside metallization structure on the first backside contact structure via a first pattern and a first etch selective to the first etch stop layer; and
forming a second backside metallization structure on the second backside contact structure via a second pattern and a second etch selective to the second etch stop layer.

16. The method of claim 15, wherein the first etch stop layer comprises silicon and nitrogen and the second etch stop layer comprises silicon and carbon.

17. The method of claim 15, wherein said replacing the first backside dummy contact structure comprises an isotropic etch process, and wherein the first etch comprises an anisotropic etch process.

18. The method of claim 15, wherein said forming the first backside metallization structure further forms a first dielectric material comprising the first etch stop layer on a backside surface of the first backside contact structure.

19. The method of claim 18, wherein said forming the second backside metallization structure further forms a second dielectric material comprising the second etch stop layer on a backside surface of the second backside contact structure.

20. The method of claim 15, further comprising:
removing, subsequent to said replacing the second backside dummy contact structure, a third backside dummy contact structure and backfilling with an isolation material.
